(19) United States
(12) Patent Application Publication
(10) Pub. No.: US 2015/0221520 A1
(43) Pub. Date: Aug. 6, 2015

(54) COMPOSITION AND METHOD FOR POLISHING MOLYBDENUM

(71) Applicant: Cabot Microelectronics Corporation, Aurora, IL (US)

(72) Inventors: Pankaj SINGH, Plainfield, IL (US); Lamon JONES, Aurora, IL (US)

(21) Appl. No.: 14/686,988

(22) Filed: Apr. 15, 2015

Related U.S. Application Data
(62) Division of application No. 13/913,721, filed on Jun. 10, 2013.

(51) Int. Cl. H01L 21/306; C09G 1/02

(52) U.S. Cl. CPC H01L 21/30625; C09G 1/02

(57) ABSTRACT

The present invention provides compositions and methods for polishing a molybdenum metal-containing surface. A polishing composition (slurry) described herein comprises an abrasive concentration of an inorganic particulate abrasive material (e.g., alumina or silica) suspended in an acidic aqueous medium containing a water soluble surface active material and an oxidizing agent. The surface active material is selected based on the zeta potential of the particulate abrasive, such that when the abrasive has a positive zeta potential, the surface active material comprises a cationic material, and when the particulate abrasive has a negative zeta potential, the surface active material comprises an anionic material, a non-ionic material, or a combination thereof.

### FIELD OF THE INVENTION

The invention relates to the semiconductor manufacturing arts. More particularly, this invention relates to compositions and methods for polishing a molybdenum surface.

### BACKGROUND OF THE INVENTION

Molybdenum metal is utilized in a number of industrial applications, including microelectronic devices (e.g., for interconnects, photo masks, and other uses). In such applications, molybdenum initially is utilized in an excess amount, and then at least some molybdenum must be removed by polishing or lapping, in a controlled manner, to achieve surface properties suitable e.g., for semiconductor device manufacture.

Abrasive materials are commonly utilized in polishing and lapping of metals. In such applications, abrasive particles are suspended in a liquid medium, such as water, sometimes with the aid of a surfactant as a dispersing agent. Polishing of metallic molybdenum surfaces often is accomplished using abrasives of varying sizes to obtain a desired surface roughness. Currently used abrasives generally require multiple steps to polish molybdenum surfaces, which can mean using multiple machines and/or parts and abrasive changes, which can adversely affect the processing time for each part.

Abrasive materials typically are suspended in a liquid carrier, such as water or an aqueous medium containing water. When the abrasive is suspended in the liquid carrier, it preferably is colloidally stable. The term “colloid” refers to the suspension of abrasive particles in the liquid carrier. “Colloidal stability” refers to the maintenance of that suspension over time. In the context of this invention, an abrasive suspension is considered colloidally stable if, when the silica is placed into a 100 mL graduated cylinder and allowed to stand without agitation for a time of 2 hours, the difference between the concentration of particles in the bottom 50 mL of the graduated cylinder ([B] in terms of g/mL) and the concentration of particles in the top 50 mL of the graduated cylinder ([T] in terms of g/mL) divided by the total concentration of particles in the abrasive composition ([C]) in terms of g/mL) is less than or equal to 0.5 (i.e., ([B]−[T])/[C]≦0.5). The value of ([B]−[T])/[C] desirably is less than or equal to 0.3, and preferably is less than or equal to 0.1.

There is an ongoing need for new compositions and methods for polishing molybdenum surfaces. The present invention addresses this need.

### BRIEF SUMMARY OF THE INVENTION

The present invention provides a method of polishing a molybdenum metal-containing surface comprising abrading the surface with a polishing slurry comprising an abrasive concentration of an inorganic particulate abrasive material, such as alumina or silica, suspended in an acidic aqueous medium containing a water soluble surface active material and an oxidizing agent (e.g., hydrogen peroxide).

In one embodiment, the aqueous CMP composition has a pH in the range of about 3 to about 6. The water soluble surface active material can be a cationic material, such as a cationic polymer or cationic surfactant. Alternatively, the surface active material can be an anionic material, a non-ionic material, or a combination thereof. The choice of the surface active material is based on the zeta potential of the particulate abrasive, such that when the abrasive has a positive zeta potential (e.g., when alumina or an aminosilane-treated silica is used), the surface active material comprises a cationic material, and when the particulate abrasive has a negative zeta potential (e.g., when native silica, such as fumed silica, is used), the surface active material comprises an anionic material, a non-ionic material, or a combination thereof.

For example, the cationic material can be a cationic polymer, or a cationic surfactant (e.g., a tetraalkylammonium compound). An example of a cationic polymer useful in the compositions and methods described herein is a poly(methacryloxyethyl trimethylammonium)halide (e.g., a chloride).

In one preferred embodiment, the aqueous CMP comprises an aqueous carrier having a pH in the range of about 3 to about 6, and contains, at point-of-use, about 0.5 to about 6 percent by weight (wt %) of a particulate abrasive (i.e., silica or alumina), about 25 to about 5,000 parts-per-million (ppm) of the water soluble surface active material, and about 0.1 to about 1.5 w/t % of the oxidizing agent.

In another aspect, the present invention provides a CMP method for polishing a molybdenum-containing substrate. The method comprises the steps of contacting a surface of the substrate with a polishing pad and an aqueous CMP composition as described herein, and causing relative motion between the polishing pad and the substrate while maintaining a portion of the CMP composition in contact with the surface between the pad and the substrate for a time period sufficient to abrade at least a portion of the molybdenum from the substrate.

### BRIEF DESCRIPTION OF THE DRAWINGS

FIG. 1 provides a graph of Mo removal rate (RR) for CMP compositions comprising various concentrations of cationic polymer (bars, left axis), as well as a plot of average roughness (boxes, right axis) obtained by polishing Mo wafers with each composition.

### DETAILED DESCRIPTION OF THE INVENTION

The present invention provides a method of polishing a molybdenum metal-containing surface comprising, consisting essentially of, or consisting of abrading the surface with a polishing slurry comprising an abrasive concentration of an inorganic particulate abrasive material (alumina or silica) suspended in an acidic aqueous medium containing a water soluble surface active agent and an oxidizing agent.

The present invention also provides a polishing composition comprising, consisting essentially of, or consisting of an acidic aqueous carrier containing an inorganic particulate abrasive material (e.g., silica or alumina), a water soluble surface active agent and an oxidizing agent. The surface active material is selected based on the zeta potential of the particulate abrasive, such that when the abrasive has a positive zeta potential, the surface active material comprises a cationic material, and when the particulate abrasive has a negative zeta potential, the surface active material comprises an anionic material, a non-ionic material, or a combination thereof.

The aqueous carrier can comprise, consist essentially of, or consist of any aqueous solvent, e.g., water, an aqueous alcohol (e.g., aqueous methanol, aqueous ethanol, aqueous ethylene glycol, and the like), and the like. Preferably, the aqueous carrier comprises deionized water.

The particulate abrasive materials useful in the CMP compositions of the invention include alumina (e.g., alpha-alumina), which has a positive zeta potential, and silica, which has a negative zeta potential in its native state, but which can be surface-modified by treatment with an aminosilane to have a positive zeta potential. A preferred type of alumina for use in the CMP composition of the invention is alpha-alumina. One preferred type of silica for use in the CMP composition of the invention is untreated (i.e., “native”) fumed silica having a negative zeta potential. In other preferred embodiments, the abrasive comprises silica, in which the surface of the silica particles have been treated with an aminosilane such as bis(trimethoxysilylpropyl)amine, e.g., SILQUEST A1170 (Crompton OSi Specialties), or a similar reactive aminosilane to adjust the zeta potential from negative to positive, by bonding basic amino groups to the surface of the silica particles and thereby neutralize acidic SiOH groups on the particle surface. Preferably, the surface-treated silica is treated with sufficient aminosilane to provide a highly positive zeta potential in the range of about 5 to about 50, if a cationic polymer or surfactant is to be included in the CMP composition.

The abrasive material preferably has a mean particle size in the range of about 50 nm to about 150 nm, more preferably 90 nm to about 120 nm. Preferably, the abrasive material is suspended in an aqueous medium at a concentration in the range of about 0.5 to about 6 wt % at point-of-use. For silica, the abrasive concentration preferably is in the range of about 2 to about 6 wt %. For alumina (e.g., alpha-alumina) the concentration of abrasive preferably is in the range of about 0.5 to about 3 wt %. As used herein, the phrase “point of use” refers to the concentration of a given component that will be used directly in a CMP process, without further dilution. The point of use concentration generally is achieved by dilution of a more concentrated composition (e.g., just before or within a few days prior to use).

The water-soluble surface active materials useful in the CMP compositions of the invention are selected based on the zeta potential of the particulate abrasive included in the composition. As described herein, cationic polymers and/or surfactants are used with abrasives having a positive zeta potential, such as ceria and aminosilane-treated colloidal silica. Optionally, the cationic material can be combined with a non-ionic polymer or surfactant, if desired. Anionic and/or non-ionic surface active materials are utilized when the abrasive has a negative zeta potential, such as native colloidal silica.

Cationic polymers useful in the compositions and methods of the present invention include homopolymers of cationic monomers, e.g., a poly(diallyldimethylammonium)halide such as poly(diallyldimethylammonium)chloride (polyDADMAC), a poly(methacryloyloxyethyltrimethylammonium)halide such as poly(methacryloyloxyethyltrimethylammonium) chloride (polyMADQUAT), and the like. In addition, the cationic polymer can be a copolymer of cationic and non-ionic monomers (e.g., alkylacrylates, alkylmethacrylates, acrylamide, styrene, and the like), such as poly(acrylamide-co-diallyldimethylammonium) chloride. Some other non-limiting examples of such cationic polymer include polyethyleneimine, ethoxylated polyethyleneimine, poly(diallyldimethylammonium)halide, poly(amidoamine), poly(methacryloyloxyethyldimethylammonium) chloride, poly(vinylpyrrolidone), poly(vinylimidazole), poly(vinylpyridine), and poly(vinylamine). A preferred cationic polymer for use in the CMP compositions of the invention is a poly(methacryloyloxyethyl trimethylammonium)halide (e.g., chloride), such as the polymer commercially available from Alco Chemical Inc. under the tradename ALCO 4773. Other suitable cationic materials include cationic surfactants, such as tetraalkylammonium compounds, e.g., hexadecyltrimethylammonium bromide, also known as cetyltrimethylammonium bromide; CTAB), 1-decyltrimethylammonium chloride (DPC), and the like.

The cationic polymer can have any suitable molecular weight. Typically, the polishing composition comprises a cationic polymer having a molecular weight of about 5 kiloDalatons (kDa) or more (e.g., about 10 kDa or more, about 20 kDa or more, about 30 kDa or more, about 40 kDa or more, about 50 kDa or more, or about 60 kDa or more) cationic polymer. The polishing composition preferably comprises a cationic polymer having a molecular weight of about 100 kDa or less (e.g., about 80 kDa or less, about 70 kDa or less, about 60 kDa or less, or about 50 kDa or less). Preferably, the polishing composition comprises a cationic polymer having a molecular weight of about 5 kDa to about 100 kDa (e.g., about 10 kDa to about 80 kDa, about 10 kDa to about 70 kDa, or about 15 kDa to about 70 kDa.

Anionic polymers useful in the compositions and methods of the present invention include, for example, homopolymers such as polyacrylic acid (PAA), polymethacrylic acid (PMAA), polymaleic acid (PMA), poly(2-acrylamido-2-methylpropanesulfonate (polyAMPS), and the like, as well as copolymers of anionic and non-ionic monomers, such as poly(acrylic acid-co-methacrylic acid), poly(acrylic acid-co-2-acrylamido-2-methyl-propanesulfonic acid), and the like. The anionic polymers can be utilized in the acidic form or as salts (e.g., sodium salts). The actual ionic character of the anionic polymer (i.e., fully ionized or partially ionized) will depend upon the pH of the CMP composition, as is well known in the art. Preferably, anionic polymers utilized in the compositions and methods of the present invention have an average molecular weight of about 100 kDa or less, for example, about 10 kDa or less, or in the range of about 1 to 10 kDa.

Non-ionic polymers useful in the compositions and methods of the present invention include, for example, polyacrylamide (PAM) homopolymers, and copolymers of acrylamide with one or more other non-ionic monomer such as methacrylamide, N-vinylpyrrolidone, and the like. Preferably, non-ionic polymers utilized in the compositions and methods of the present invention have an average molecular weight of about 100 kDa or less, for example, about 10 kDa or less, or in the range of about 1 to 10 kDa.

In some preferred embodiments the water-soluble surface active material (e.g., polymer or surfactant) is present in the composition at a concentration in the range of about 25 to about 5,000 parts-per-million (ppm), e.g., about 100 to about 1,000 ppm.

The abrasive desirably is suspended in the CMP composition, more specifically in the aqueous component of the CMP composition, and is colloidally stable. The term colloid refers to the suspension of abrasive particles in the liquid carrier. Colloidal stability refers to the maintenance of that suspension over time.

In some embodiments, an alumina abrasive or an aminosilane-treated colloidal silica abrasive is used in conjunction with a cationic material (e.g., a polymer or surfactant) in the CMP composition of the present invention. Alumina and aminosilane-treated colloidal silica have positive zeta potentials, which complement the zeta potential of a cationic polymer, and allow both components to exist within the same composition without precipitation of components. Inclusion of a cationic polymer such as ALCO 4773 in the CMP composition reduces surface defects on the molybdenum being polished, relative to CMP compositions lacking the cationic material.

In other embodiments, the abrasive material component of the CMP composition comprises native silica (e.g., fumed silica) having a negative zeta potential, preferably in conjunction with an anionic polymer and/or a non-ionic polymer in the CMP composition of the present invention. PAA and PAM, for example, advantageously form colloidally stable slurries with silica, due to the negative zeta potential of the silica. Some non-ionic polymers such as low molecular weight polyethylene glycols, polyvinylpyrrolidone or polyvinylalcohol typically do not form colloidally stable slurries in the CMP composition of the present invention, at least when utilized on their own. Anionic polymers such as PAA or non-ionic polymers such as PAM reduce surface defects on the molybdenum surface being polished.

The polishing composition has an acidic pH, e.g., in the range of about 3 to about 6. The pH of the polishing composition can be achieved and/or maintained by any suitable means. For example, the pH can be maintained through the use of a suitable buffer, if desired. In addition, the other components of the composition (e.g., the abrasive and the surface active agent) also help to establish and maintain the pH. More specifically, the polishing composition can further comprise a pH adjustor, a pH buffering agent, or a combination thereof. The pH adjustor can comprise, consist essentially of, or consist of any suitable pH-adjusting compound. For example, the pH adjustor can be the acid of the polishing composition. The pH buffering agent can be any suitable buffering agent, for example, phosphates, acetates, borates, sulfonates, carboxylates, ammonium salts, and the like. The polishing composition can comprise any suitable amount of a pH adjustor and/or a pH buffering agent, provided such amount is sufficient to achieve and/or maintain the desired pH of the polishing composition, e.g., within the ranges set forth herein.

The polishing composition also comprises an oxidizing agent, which can be any suitable oxidizing agent for one or more materials of the substrate to be polished with the polishing composition. Preferably, the oxidizing agent is selected from the group consisting of a bromate, a bromite, a chlorate, a chlorite, hydrogen peroxide, a hypochlorite, an iodate, a monoperoxysulfate, a monoperoxysulfite, a monoperoxyphosphate, a monoperoxyhypophosphate, a monoperoxypyrophosphate, an organo-halo-oxy compound, a periodate, a permanganate, peroxyacetic acid, a ferric salt (e.g., ferric nitrate), and a combination of two or more thereof. The oxidizing agent can be present in the polishing composition in any suitable amount. Typically, the polishing composition comprises about 0.01 wt. % or more (e.g., about 0.02 wt. % or more, about 0.1 wt. % or more, about 0.5 wt. % or more, or about 1 wt. % or more) oxidizing agent. The polishing composition preferably comprises about 2 wt % or less (e.g., about 0.1 to about 1.5 wt % at point of use) of the oxidizing agent when a “strong” oxidizer is used. Hydrogen peroxide is a particularly preferred strong oxidizing agent. For weaker oxidizing agents, such as ferric nitrate, a higher concentration (e.g., up to about 10 wt % or more) may be required or desired.

It will be appreciated that many of the aforementioned compounds (e.g., polymers, surfactants, acids, buffering agents) can exist in the form of a salt (e.g., a metal salt, an ammonium salt, or the like), an acid, or as a partial salt. Furthermore, certain compounds or reagents may perform more than one function. For example, some compounds can function both as a chelating agent and an oxidizing agent (e.g., certain ferric nitrates and the like).

The polishing slurries of the present invention also can be provided as a concentrate, which is intended to be diluted with an appropriate amount of aqueous solvent (e.g., water) prior to use. In such an embodiment, the polishing slurry concentrate can include the various components dispersed or dissolved in aqueous solvent in amounts such that, upon dilution of the concentrate with an appropriate amount of aqueous solvent, each component of the polishing composition will be present in the polishing composition in an amount within the appropriate range for use.

The polishing slurries of the invention can be prepared by any suitable technique, many of which are known to those skilled in the art. The polishing slurry can be prepared in a batch or continuous process. Generally, the polishing slurry can be prepared by combining the components thereof in any order. The term “component” as used herein includes individual ingredients (e.g., abrasive, polymer, surfactant, acids, bases, buffers, oxidizing agents, and the like), as well as any combination of ingredients. For example, the abrasive can be dispersed in water, the surface active material, and any other additive material can be added, and mixed by any method that is capable of incorporating the components into the polishing slurry. The pH can be further adjusted, if desired, at any suitable time by addition of an acid, base or a buffer, as needed. Preferably, the oxidizing agent in passed to the composition shortly before use (e.g., a few minutes to a few days before use).

The CMP methods of the present invention are particularly suited for use in conjunction with a chemical-mechanical polishing apparatus. Typically, the CMP apparatus comprises a platen, which, when in use, is in motion and has a velocity that results from orbital, linear, and/or circular motion, a polishing pad in contact with the platen and moving with the platen when in motion, and a carrier that holds a substrate to be polished in contact with the pad and moving relative to the surface of the polishing pad. A CMP composition is typically pumped onto the polishing pad to aid in the polishing process. The polishing of the substrate is accomplished by the combined abrasive action of the moving polishing pad and the CMP composition of the invention present on the polishing pad, which abrades at least a portion of the surface of the substrate, and thereby polishes the surface.

A substrate can be planarized or polished with a CMP composition of the invention using any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof.

Desirably, the CMP apparatus further comprises an in situ polishing endpoint detection system, many of which are known in the art. Techniques for inspecting and monitoring the polishing process by analyzing light or other radiation reflected from a surface of the workpiece are known in the art. Such methods are described, for example, in U.S. Pat. No. 5,196,353 to Sandhu er al., U.S. Pat. No. 5,433,651 to Lustig et al., U.S. Pat. No. 5,949,927 to Tang, and U.S. Pat. No. 5,964,643 to Birang et al. Desirably, the inspection or monitoring of the progress of the polishing process with respect to a workpiece being polished enables the determination of the polishing end-point, i.e., the determination of when to terminate the polishing process with respect to a particular workpiece.

The following non-limiting examples are provided to illustrate preferred embodiments of the methods of the present invention.

### Example 1

Sintered molybdenum wafers (2-inch square) were polished for about 20 minutes with CMP slurries on a HYPREZ Model 15 polisher with an EPIC D100 polishing pad (concentric grooving; 1 minute ex situ conditioning between wafers with a TBW conditioner) at a down force (DF) of about 9.4 pounds-per-square inch (psi), a platen speed of about 75 revolutions-per-minute (rpm) and a slurry flow rate of about 75 milliliters-per-minute (mL/min).

Polishing slurries containing about 2, 6, and 12 wt % alpha-alumina in water at pH 4 provided Mo removal rates (RR) of about 490, 650, and 830 nanometers-per-hour (nm/hr), respectively, indicating the increasing abrasive concentration leads to higher removal rates. The Mo surfaces exhibited an average roughness (Ra) of about 290 to 325 Angstroms (Å). Use of 5 wt % fumed silica in place of alumina lead to a Mo removal rate of about 210 nm/hr at pH 4. Decreasing the pH to about 2.3 increased the RR to about 240 nm/hr with the silica slurry, whereas increasing the pH to 8 and 10 lead to removal rates of about 180 to 190 nm/hr. Electrochemical evaluation indicated that the silica slurries exhibited an oxidation potential in the corrosion region at all pH values (see Table 1).

TABLE 1

| | With Abrasion | | After abrasion | |
|---|---|---|---|---|
| Slurry pH | E_{corr} (mV) | i_{corr} (μA/cm²) | E_{corr} (mV) | i_{corr} (μA/cm²) |
| 2.3 | −536 | 5 | −425 | 2 |
| 8.0 | −693 | 14 | −689 | 11 |

Addition of an oxidizing agent (14 to 140 ppm ferric nitrate, 0.2 wt % hydrogen peroxide, 0.2 wt % potassium periodate, or 0.2 wt % potassium permanganate) to the slurries resulted in higher oxidation and corrosion and unsuitable surface roughness characteristics.

### Example 2

The effectiveness of corrosion inhibitors in abrasive slurries containing oxidizing agents was evaluated. Slurries comprising 2 wt % alpha-alumina and 0.2 wt % hydrogen peroxide at pH 4 were evaluated with traditional inhibitors used in copper polishing (glycine, 1,2,4-triazole, benzotriazole, 5-aminotetrazole) still afforded higher than desirable surface roughness. Fumed silica slurries showed similar results with glycine, lysine, and cationic polymer (polyMADQUAT; ALCO 4773).

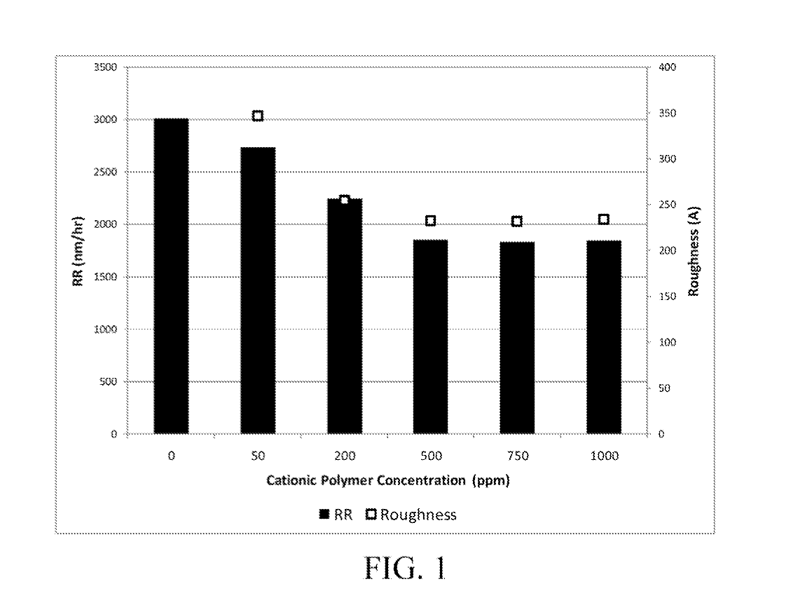

In contrast to the results with fumed silica, alpha-alumina slurries including polyMADQUAT (50 to 1000 ppm) provided suitable Mo removal rates (RR; about 1700 to 2700 nm/hr) and suitable roughness (Ra; about 225 to 350 Å (see FIG. 1). For comparison, an alpha-alumina composition having the same formulation, but without the polyMADQUAT (first bar in FIG. 1), exhibited heavy surface staining and corrosion, resulting in an unacceptably rough surface beyond the scale of the plot in FIG. 1.

These results demonstrate that addition of a water soluble surface active material to polishing compositions comprising an abrasive and an oxidizing agent can provide unexpected improvements in surface roughness when the surface active agent is selected to complement the zeta potential of the abrasive (e.g., cationic polymer plus positive zeta potential abrasive), compared to slurries without added surface active agent, or with surface active agent and incompatible zeta potential (e.g., silica with polyMADQUAT).

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as” or “for example”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A chemical-mechanical polishing (CMP) method for polishing a molybdenum-containing substrate comprising the steps of:
(a) contacting a surface of the substrate with a polishing pad and an aqueous CMP composition comprising an aqueous carrier having a pH in the range of about 3 to about 6 and containing, at point of use:
(a) a particulate abrasive selected from the group consisting of a silica abrasive and an alumina abrasive;
(b) a water soluble surface active material; and
(c) an oxidizing agent;
wherein the surface active material is selected based on the zeta potential of the particulate abrasive, such that when the abrasive has a positive zeta potential, the surface active material comprises a cationic material, and when the particulate abrasive has a negative zeta potential, the surface active material comprises an anionic material, a non-ionic material, or a combination thereof; and
(b) causing relative motion between the polishing pad and the substrate while maintaining a portion of the CMP composition in contact with the surface between the pad and the substrate for a time period sufficient to abrade at least a portion of the molybdenum from the substrate.

2. The CMP method of claim 1 wherein the particulate abrasive comprises alpha-alumina and the surface active agent is a cationic material.

3. The CMP method of claim 2 wherein the cationic material is a cationic polymer.

4. The CMP method of claim 3 wherein the cationic polymer comprises a poly(methacryloxyethyltrimethylammonium)halide.

5. The CMP method of claim 3 wherein oxidizing agent comprises hydrogen peroxide.

6. The CMP method of claim 1 wherein the particulate abrasive comprises silica and the surface active material is an anionic material, a non-ionic material or a combination thereof.

7. The CMP method of claim 6 wherein the surface active material comprises a poly(acrylic acid), a polyacrylamide, or a combination thereof.

8. The CMP method of claim 6 wherein oxidizing agent comprises hydrogen peroxide.

9. The CMP method of claim 1 wherein the particulate abrasive comprises an aminosilane surface-treated silica having a positive zeta potential, and the surface active material comprises cationic material.

10. The CMP method of claim 9 wherein the cationic material is a cationic polymer.

11. The CMP method of claim 10 wherein the cationic polymer comprises a poly(methacryloxyethyl trimethylammonium)halide.

12. The CMP method of claim 9 wherein the oxidizing agent comprises hydrogen peroxide.

13. The CMP method of claim 1 wherein the oxidizing agent comprises hydrogen peroxide.

14. A chemical-mechanical polishing (CMP) method for polishing a molybdenum-containing substrate comprising the steps of:
(a) contacting a surface of the substrate with a polishing pad and an aqueous CMP composition comprising an aqueous carrier having a pH in the range of about 3 to about 6 and containing, at point of use:
(i) about 0.5 to about 6 wt % of a particulate abrasive selected from the group consisting of a silica abrasive and an alumina abrasive;
(ii) about 25 to about 5,000 ppm of a water soluble surface active material; and
(iii) about 0.1 to about 1.5 wt % of an oxidizing agent.
wherein the surface active material is selected based on the zeta potential of the particulate abrasive, such that when the abrasive has a positive zeta potential, the surface active material comprises a cationic material, and when the particulate abrasive has a negative zeta potential, the surface active material comprises an anionic material, a non-ionic material, or a combination thereof; and
(b) causing relative motion between the polishing pad and the substrate while maintaining a portion of the CMP composition in contact with the surface between the pad and the substrate for a time period sufficient to abrade at least a portion of the molybdenum from the substrate.

15. The CMP method of claim 14 wherein the particulate abrasive comprises alpha-alumina or an aminosilane surface-treated silica, and has a positive zeta potential, and the water soluble surface active material comprises a poly(methacryloyloxyethyl trimethylammonium)halide.

16. The CMP method of claim 15 wherein the oxidizing agent comprises hydrogen peroxide.

17. The CMP method of claim 14 wherein the particulate abrasive comprises a silica having a negative zeta potential, and the water soluble surface active material comprises a poly(acrylic acid), a polyacrylamide, or a combination thereof.

18. The CMP method of claim 17 wherein the oxidizing agent comprises hydrogen peroxide.
